(19) United States
(12) Patent Application Publication
(10) Pub. No.: US 2006/0199037 A1
(43) Pub. Date: Sep. 7, 2006

(54) Light emitting element, display unit and electronic apparatus

(75) Inventor: Katsuyuki Morii, Lausanne (CH)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/336,775

(22) Filed: Jan. 23, 2006

(30) Foreign Application Priority Data
Mar. 3, 2005 (JP) 2005-059467

(51) Int. Cl. H01L 51/50; H05B 33/12

(52) U.S. Cl. 428/690; 428/917; 313/504; 313/506; 313/509

(57) ABSTRACT

A light emitting element that includes a first electrode, a second electrode, a luminescent layer that is placed between the first electrode and the second electrode, a carrier transport layer that is placed between the first electrode and the second electrode, and an intermediate layer that is placed between the carrier transport layer and the first electrode, wherein at least one of either the luminescent layer or the carrier transport layer contains a high-molecular material and the intermediate layer contains at least either of a semiconductor material or an insulating material.

### BACKGROUND

1. Technical Field

The present invention relates to a light emitting element, a display unit and an electronic apparatus.

2. Related Art

An organic electroluminescence element (hereinafter simply referred to as an “organic EL element”) in which at least one layer of a luminescent organic material (organic electroluminescence layer) is interposed between a cathode and an anode can significantly lower the amount of voltage to be applied as compared to an inorganic EL element, making it possible to produce an element with a wide variety of luminescent colors (refer, for example, to Appl. Phys. Lett. 51(12), 21 Sep. 1987, p. 913, Appl. Phys. Lett. 71(1), 7 Jul., 1997, p. 34, Nature 357,477 1992, JP-A-10-153967, JP-A-10-12377 and JP-A-11-40358).

Presently, various kinds of device architectures, including the development and improvement of materials, are proposed and active studies are being conducted for getting organic EL elements with a higher efficiency.

As for such organic EL elements, elements with various kinds of luminescent colors and elements with high luminance and with high efficiency are under development. Various kinds of practical application of such elements, such as for use in display units as a pixel, use as a light source and the like, are now being reviewed.

Further, various studies are under way to further improve the light emitting efficiency toward the practical use.

### SUMMARY

An advantage of the invention is to provide a light emitting element having high light emitting efficiency and high durability (life span), a highly reliable display unit having the light emitting element, and an electronic apparatus.

The advantage is achieved by the invention in the following way.

A first aspect of the invention is to provide a light emitting element that includes a first electrode, a second electrode, a luminescent layer that is placed between the first electrode and the second electrode, a carrier transport layer that is placed between the first electrode and the second electrode, and an intermediate layer that is placed between the carrier transport layer and the first electrode, wherein at least one of either the luminescent layer or the carrier transport layer contains a high-molecular material and the intermediate layer contains at least either of a semiconductor material or an insulating material.

Thus, a light emitting element having a high light emitting efficiency and high durability (life span) can be provided.

It is preferable in the light emitting element according to the first aspect of the invention that the carrier transport layer is placed between the luminescent layer and the first electrode.

It is preferable in the light emitting element according to the first aspect of the invention that the semiconductor material is mainly composed of vanadium oxide.

Thus, the light emitting efficiency and the durability (life span) can be further improved.

It is preferable in the light emitting element according to the first aspect of the invention that the insulating material is mainly composed of silicon oxide.

Thus, the light emitting efficiency and the durability (life span) can be further improved.

It is preferable in the light emitting element according to the first aspect of the invention that the intermediate layer has an average thickness of less than 5 nm.

The intermediate layer fully exerts its function with such a film thickness.

It is preferable in the light emitting element according to the first aspect of the invention that the intermediate layer is formed by vapor deposition.

Thus, the intermediate layer gets densified and the performance is improved.

It is preferable in the light emitting element according to the first aspect of the invention that the intermediate layer is in contact with the first electrode.

Thus, the enlargement of the light emitting element (in particular, the thickening of the film) and the lowering of the injection efficiency of the carrier into the luminescent layer can be prevented.

It is preferable in the light emitting element according to the first aspect of the invention that the intermediate layer is in contact with the carrier transport layer.

Thus, the enlargement of the light emitting element (in particular, the thickening of the film) and the lowering of the injection efficiency of the carrier into the luminescent layer can be prevented.

It is preferable in the light emitting element according to the first aspect of the invention that the luminescent layer contains a high-molecular material and the intermediate layer has a function of preventing the exciton generated in the luminescent layer from contacting the first electrode.

It is preferable in the light emitting element according to the first aspect of the invention that the high-molecular material constituting the luminescent layer is polyfluorene or any of its derivatives.

Thus, the light emitting efficiency of the luminescent layer can be further improved.

It is preferable in the light emitting element according to the first aspect of the invention that the carrier transport layer contains a high-molecular material and the intermediate layer has a function of preventing the carrier injected from the second electrode from reaching the first electrode.

It is preferable in the light emitting element according to the first aspect of the invention that the carrier transport layer is a hole transport layer and the high-molecular material constituting the hole transport layer is poly-arylamin or any of its derivatives.

Thus, the hole transportability of the hole transport layer can be improved.

It is preferable in the light emitting element according to the first aspect of the invention that the luminescent layer and the carrier transport layer are formed simultaneously by phase separation.

Thus, the light emitting efficiency and the durability (life span) can be further improved. It is particularly effective to place an intermediate layer in a light emitting element according to the configuration.

A second aspect of the invention is to provide a display unit that includes a light emitting element according to the first aspect of the invention.

Thus, a highly reliable display unit can be provided.

A third aspect of the invention is to provide an electronic apparatus that includes a display unit according to the second aspect of the invention.

Thus, a highly reliable electronic apparatus can be provided.

### BRIEF DESCRIPTION OF THE DRAWINGS

The invention will be described with reference to the accompanying drawings, wherein like numbers reference like elements.

FIG. 1 is a diagram showing an example of the vertical section of a light emitting element according to an embodiment of the invention.

FIG. 2 is a diagram showing an example of the vicinity of the interface of each part (each layer) of the light emitting element shown in FIG. 1.

FIG. 3 is a diagram further magnifying FIG. 2.

FIG. 4 is a drawing showing an example of the longitudinal section of a display device having a display unit according to an embodiment of the invention.

FIG. 5 is an oblique diagram showing an example of the configuration of mobile (or notebook) personal computers having an electronic apparatus according to an embodiment of the invention.

FIG. 6 is an oblique diagram showing an example of the configuration of mobile phones (including a PHS) having an electronic apparatus according to an embodiment of the invention.

FIG. 7 is an oblique diagram showing an example of the configuration of digital still cameras having an electronic apparatus according to an embodiment of the invention.

FIG. 8 is a chart showing the result of evaluating the light emitting efficiency of the light emitting elements that are produced according to each of the embodiments and a comparative example.

FIG. 9 is a chart showing the result of evaluating the life span of the light emitting elements that are produced according to each of the embodiments and a comparative example.

### DESCRIPTION OF EXEMPLARY EMBODIMENTS

A light emitting element, a display unit and an electronic apparatus according to preferred embodiments of the invention will now be described in detail with reference to the drawings.

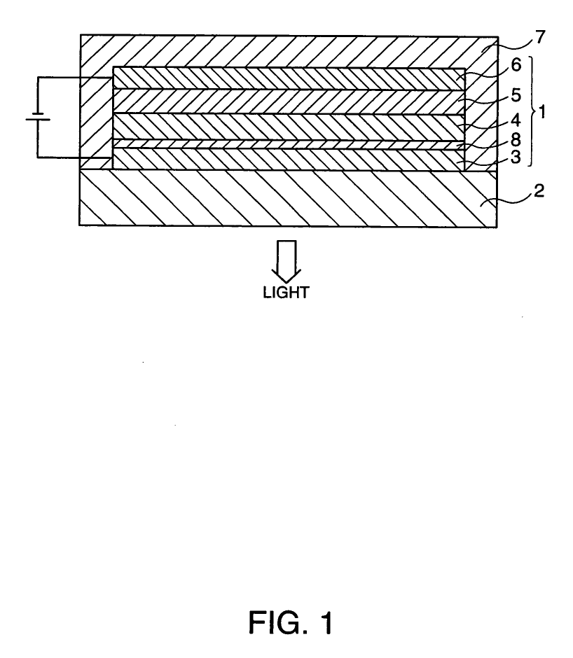

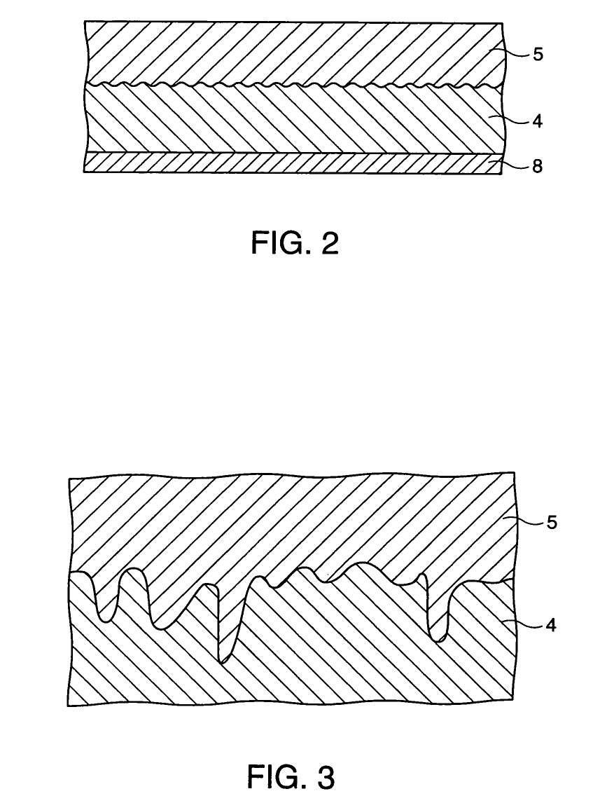

FIG. 1 is a diagram showing an example of the vertical section of a light emitting element according to an aspect of the invention. FIG. 2 is a diagram showing an example of the vicinity of the interface of each part (each layer) of the light emitting element shown in FIG. 1. FIG. 3 is a diagram further magnifying FIG. 2. In the following description, the upper side is referred to as “up” and the downside is referred to as “down” in FIGS. 1 to 3 for the sake of explanation.

The light emitting element (electroluminescent element) 1 shown in FIG. 1 is composed of an anode (first electrode) 3 and a cathode (second electrode) 6, with a hole transport layer (carrier transport layer) 4 and a luminescent layer 5 being interposed respectively on the side of the anode 3 and on the side of the cathode 6, between the anode 3 and the cathode 6 (between a pair of electrodes) and, in addition, with an intermediate layer 8 being interposed between the hole transport layer 4 and the anode 3. Moreover, the entire part of the light emitting element 1 is placed on a substrate 2, sealed with a sealant 7.

The substrate 2 acts as a support medium for the light emitting element 1. Because the light emitting element 1 of the embodiment has a structure in which light exits from the side of the substrate 2 (a bottom emission type), the substrate 2 and the anode 3 are both practically transparent (colorless transparent, colored transparent or semitransparent).

Examples of a constituent material for the substrate 2 include: resin materials such as polyethylene terephthalate, polyethylene naphthalate, polypropylene, cycloolefin polymer, polyamide, polyethersulfone, polymethyl methacrylate, polycarbonate, polyalylate; glass materials such as quartz glass and soda glass. These materials can be used singly or in combination of two or more.

Although the average thickness of the substrate 2 is not particularly limited, it is preferable to be between about 0.1 and 30 mm, more preferably between about 0.1 and 10 mm.

In the case where the light emitting element 1 has a structure in which light exits from the other side than the one that is in contact with the substrate 2 (a top emission type), either a transparent substrate or an opaque substrate can be used for the substrate 2.

Examples of an opaque substrate include a substrate composed of a ceramics material such as alumina, a metal substrate such as stainless steel on the surface of which an oxide film (insulating film) is formed, a substrate composed of a resin material, and the like.

The anode 3 is an electrode for injecting a hole into a hole transport layer 4 to be described later. As a constituent material for the anode 3, it is preferable to use a highly conductive material with a high work function.

Examples of a constituent material for the anode 3 include: oxide such as ITO (indium tin oxide), IZO (indium zinc oxide), In303, Sn02, Sb—SnO2, AI—ZnO; and Au, Pt, Ag, Cu and a metal alloy containing them and the like. These materials can be used singly or in combination of two or more.

Although the average thickness of the anode 3 is not particularly limited, it is preferable to be between about 10 and 200 nm, more preferably between about 50 and 150 nm.

Meanwhile, the cathode 6 is an electrode for injecting an electron into a luminescent layer 5 to be described later. As a constituent material for the cathode 6, it is preferable to use a material with a low work function.

Examples of a constituent material for the cathode 6 include: Li, Mg, Ca, Sr, La, Ce, Er, Eu, Sc, Y, Yb, Ag, Cu, Al, Cs, Rb and a metal alloy containing them and the like. These materials can be used singly or in combination of two or more (for example, a multilayer body having a plurality of layers).

It is preferable, in particular in the case of using a metal alloy as a constituent material for the cathode 6, to use a metal alloy including a stable metal element such as Ag, Al, Cu and the like. Specifically, it is preferable to use a metal alloy such as MgAg, AlLi, CuLi and the like. Using such a metal alloy as a constituent material for the cathode 6 improves the electron injection efficiency and the stability of the cathode 6.

Although the average thickness of the cathode 6 is not particularly limited, it is preferable to be between about 100 and 10,000 nm, more preferably between about 200 and 500 nm.

The optical translucency is not particularly required for the cathode 6 because the light emitting element 1 according to the embodiment is of a bottom emission type.

The hole transport layer 4 has a function of transporting the hole that is injected from the anode 3 to the luminescent layer 5.

As a constituent material for the hole transport layer 4, any of various p-type high-molecular materials or various p-type low-molecular materials can be used, either singly or in combination of two or more.

Examples of a p-type high-molecular material (organic polymer) include: compounds having an arylamin structure such as poly-arylamin; compounds having a fluorine structure such as fluorine-bithiophene copolymer; compounds having both an arylamin structure and a fluorine structure such as fluorine-arylamin copolymer; poly(N-vinylcarbozole), polyvinylpyrene, polyvinylanthracene, polythiophene, polyalkylthiophene, polyhexylthiophene, poly(p-phenylenevinylene), polyphenylenevinylene, pyreneformaldehyde resin, ethylcarbazoleformaldehyde resin and any of its derivatives, and the like.

Further, the above-mentioned compounds can be also used as a mixture with other compounds. Examples of a mixture containing polythiophene include poly(3,4-ethylene dioxythiophene):poly(styrene sulfonic acid)(PEDOT/PSS) and the like.

Meanwhile, examples of a p-type low-molecular material include: arylcycloalkane-based compounds such as 1,1-bis(4-di-para-triaminophenyl)-cyclohexane and 1,1′-bis(4-di-para-tolylaminophenyl)-4-phenyl-cyclohexane; arylamine-based compounds such as 4,4′,4″-trimethyltriphenylamine, N,N,N′,N′-tetraphenyl-1,1′-biphenyl-4,4′-diamine, N,N′-diphenyl-N,N′-bis(3-methylphenyl)-1,1′-biphenyl-4,4′-diamine(TPD1), N,N′-diphenyl-N,N′-bis(4-methoxyphenyl)-1,1′-biphenyl-4,4′-diamine(TPD2), N,N,N′,N′-tetrakis(4-methoxyphenyl)-1,1′-biphenyl-4,4′-diamine(TPD3), N,N′-di(1-naphthyl)-N,N′-diphenyl-1,1′-biphenyl-4,4′-diamine(alpha-NPD), TPTE; phenylenediamine-based compounds such as N,N,N′,N′-tetraphenyl-para-phenylenediamine, N,N,N′,N′-tetra(para-tolyl)-para-phenylenediamine and N,N,N′,N′-tetra(meta-tolyl)-meta-phenylenediamine(PDA); carbazole-based compounds such as carbazole, N-isopropylcarbazole and N-phenylcarbazole; stilbene-based compounds such as stilbene and 4-di-para-tolylaminostilbene; oxazole-based compounds such as OxZ; triphenylmethane-based compounds such as triphenylmethane and m-MTDATA; pyrazoline-based compounds such as 1-phenyl-3-(para-dimethylaminophenyl)pyrazoline; benzine(cyclohexadiene)-based compounds; triazole-based compounds such as triazole; imidazole-based compounds such as imidazole; oxadiazole-based compounds such as 1,3,4-oxadiazole and 2,5-di(4-dimethylaminophenyl)-1,3,4-oxadiazole; anthracene-based compounds such as anthracene and 9-(4-diethylaminostyryl)anthracene; fluorenone-based compounds such as fluorenone, 2,4,7-trinitro-9-fluorenone and 2,7-bis(2-hydroxy-3-(2-chlorophenylcarbamoyl)-1-naphthylazo)fluorenone; aniline-based compounds such as polyaniline; silane-based compounds; pyrrole-based compounds such as 1,4-dithioketo-3,6-diphenyl-pyrrolo-(3,4-c)pyrrolopyrrole; fluoren-based compounds such as fluoren; porphyrin-based compounds such as porphyrin and metal tetraphenylporphyrin; quinacridon-based compounds such as quinacridon; metallic or non-metallic phthalocyanine-based compounds such as phthalocyanine, copper phthalocyanine, tetra(t-butyl)copper phthalocyanine and iron phthalocyanine; metallic or non-metallic naphthalocyanine-based compounds such as copper naphthalocyanine, vanadyl naphthalocyanine and monochloro gallium naphthalocyanine; and benzidine-based compounds such as N,N′-di(naphthalene-1-yl)-N,N′-diphenyl-benzidine and N,N,N′,N′-tetraphenylbenzidine.

Among these, a compound composed mainly of a high-molecular material is preferred as a constituent material for the hole transport layer 4. Constituting the hole transport layer 4 using a high-molecular material as a main ingredient improves the hole transportability.

Further, using a high-molecular material (high-molecular light emitting material) as a constituent material for the luminescent layer 5 makes it possible to form the hole transport layer 4 and the luminescent layer 5 simultaneously by phase separation (vertical phase separation). The resulting effects will be described later.

A high-molecular material mainly composed of poly(allylamine) or any of its derivatives is particularly preferred as a constituent material for the hole transport layer 4. Thus, the resulting effects can be further improved.

Here, examples of poly(allylamine) derivatives include a triphenylamine-based polymer molecule as shown in the chemical diagram 1 below.

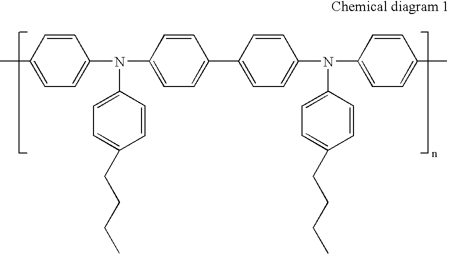

Although the average thickness of the hole transport layer 4 is not particularly limited, it is preferable to be between about 10 and 150 nm, more preferably between about 30 and 100 nm.

A luminescent layer 5 is placed in contact with the hole transport layer 4. The luminescent layer 5 transports the electron injected from the cathode 6 and receives a hole from the hole transport layer 4. Then, the hole and the electron are recombined in the vicinity of the interface with the hole transport layer 4. The energy discharged in the recombination generates an exciton, which discharges (emits) energy (such as fluorescence or phosphorescence) in getting back to the normal state.

As a constituent material for the luminescent layer 5, any of various high-molecular light emitting materials (high-molecular materials) and various low-molecular light emitting materials (low-molecular materials) can be used, either singly or in combination of two or more.

Examples of a high-molecular light emitting material include: polyacetylene-based compounds such as trans-type polyacetylene, cis-type polyacetylene, poly(di-phenylacetylene) (PDPA) and poly(alkyl, phenylacetylene) (PAPA); polyparaphenylenevinylene-based compounds such as poly(para-phenylenevinylene) (PPV), poly(2,5-dialkoxy-para-phenylenevinylene) (RO-PPV), cyano-substituted-poly(para-phenylenevinylene) (CN-PPV), poly(2-dimethyloctylsilyl-para-phenylenevinylene) (DMOS-PPV) and poly(2-methoxy, 5-(2′-ethylhexoxy)-para-phenylenevinylene) (MEH-PPV); polythiophene-based compounds such as poly(3-alkylthiophene) (PAT) and poly(oxypropylene)triol (POPT); polyfluorene-based compounds such as poly(9,9-dialkylfluorene) (PDAF), poly(dioctylfluorene-alt-benzothiadiazole) (F8BT), alpha, omega-bis[N,N-di(methylphenyl)aminophenyl]-poly[9,9-bis(2-ethylhexyl)fluoren-2,7-diyl](PF2/6 am4) and poly(9,9′-dioctyl-2,7-divinylenefluorenylene)-alt-co(anthracene-9,10-diyl), polyparaphenylene-based compounds such as poly(para-phenylene) (PPP) and poly(1,5-dialkoxy-para-phenylene) (RO-PPP); polycarbazole-based compounds such as poly(N-vinylcarbazole) (PVK); and polysilane-based compounds such as poly(methylphenylsilane) (PMPS), poly(naphthylphenylsilane) (PNPS), and poly(biphenylylphenylsilane) (PBPS).

Meanwhile, examples of a low-molecular light emitting material include: various metallic complexes such as 3 coordination iridium complex having, on a ligand, 2,2′-bipyridine-4,4′-dicarboxylic acid as shown in the chemical diagram 2 below, factris(2-phenylpyridine)iridium (Ir(ppy)₃), 8-hydroxyquinoline aluminum (Alq3), tris(4-methyl-8-quinolinolate) aluminum(III) (Almq3), 8-hydroxyquinoline zinc (Znq2), (1,10-phenanthroline)-tris-(4,4,4-trifluoro-1-(2-thienyl)-butane-1,3-dionate) europium(III) (Eu(TTA)3(phen)) and 2,3,7,8,12,13,17,18-octaethyl-21H, 23H-porphin platinum(II); benzene-based compounds such as distyrylbenzene (DSB) and diaminodistyrylbenzene (DADSB); naphthalene-based compounds such as naphthalene and Nile red; phenanthrene-based compounds such as phenanthrene; chrysene-based compounds such as chrysene and 6-nitrochrysene; perylene-based compounds such as perylene; coronene-based compounds such as coronene; anthracene-based compounds such as anthracene and bisstyrylanthracene; pyrene-based compounds such as pyrene; pyran-based compounds such as 4-(di-cyanomethylene)-2-methyl-6-(para-dimethylaminostyryl)-4H-pyran (DCM); acridine-based compounds such as acridine; stilbene-based compounds such as stilbene; thiophene-based compounds such as 2,5-dibenzooxazolethiophene; benzooxazole-based compounds such as benzooxazole; benzoimidazole-based compounds such as benzoimidazole; benzothiazole-based compounds such as 2,2′-(para-phenylenedivinylene)-bisbenzothiazole; butadiene-based compounds such as bistyryl(1,4-diphenyl-1,3-butadiene) and tetraphenylbutadiene; naphthalimide-based compounds such as naphthalimide; coumarin-based compounds such as coumarin; perynone-based compounds such as perynone; oxadiazole-based compounds such as oxadiazole; aldazine-based compounds; cyclopentadiene-based compounds such as 1,2,3,4,5-pentaphenyl-1,3-cyclopentadiene (PPCP); quinacridone-based compounds such as quinacridone and quinacridone red; pyridine-based compounds such as pyrrolopyridine and thiadiazolopyridine; spiro compounds such as 2,2′,7,7′-tetraphenyl-9,9′-spirobifluorene; metallic or non-metallic phthalocyanine-based compounds such as phthalocyanine (H2Pc) and copper phthalocyanine; and fluorene-based compounds such as fluorene.

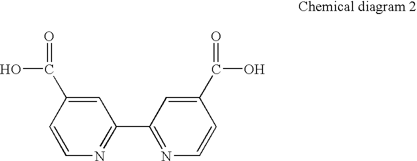

Among these, a compound mainly composed of a high-molecular light emitting material is preferred as a constituent material for the luminescent layer 5. Constituting the luminescent layer 5 using a high-molecular light emitting material as a main ingredient improves the light emitting efficiency.

Further, as described above, using a high-molecular material as a constituent material for the hole transport layer 4 makes it possible to form the hole transport layer 4 and the luminescent layer 5 simultaneously by phase separation (vertical phase separation).

A high-molecular light emitting material mainly composed of polyfluorene or any of its derivatives is particularly preferred as a constituent material for the luminescent layer 5. Thus, the resulting effects can be further improved.

For the reasons as mentioned above, it is preferable to constitute both the hole transport layer 4 and the luminescent layer 5 by using a high-molecular material as a main ingredient. In such a case, it is preferable that the hole transport layer 4 and the luminescent layer 5 are formed simultaneously by phase separation.

Here, the interface of the luminescent layer 5 and the hole transport layer 4 that are formed simultaneously by phase separation is almost in parallel with the top surface of the anode 3 in broad perspective, as shown in FIG. 2, while the layers are intimately in contact with each other (overlap each other) in a concavo-convex way in microscopic perspective, as shown in FIG. 3.

Thus, the contact surface between the luminescent layer 5 and the hole transport layer 4 increases, expanding the recombination site for the electron and the hole. Here, because the recombination site is located on a remote part from the electrodes (the anode 3 and the cathode 6), the light emitting site is expanded accordingly (the number of molecules that contribute to light emitting increases). Thus, the light emitting efficiency and the life span of the light emitting element 1 can be further improved.

Further, because the interface between the luminescent layer 5 and the hole transport layer 4 is not even (flat) but concavo-convex, the simultaneous excitation and binding of the hole and the electron can be prevented even when the driving voltage is increased. Thus, in turn, the rapid uprise of the light emitting intensity can be also prevented. Therefore, the brightness can be moderately increased according to the driving voltage, which makes it easy to control the light emitting brightness of the light emitting element 1 as well as to control its tone in low brightness. There is also an advantage in that the need for a complex peripheral circuit for minutely controlling the driving voltage is eliminated.

Although the average thickness of the luminescent layer 5 is not particularly limited, it is preferable to be between about 1 and 100 nm, more preferably between about 20 and 50 nm.

The sealant 7 is placed in a manner of covering the anode 3, the hole transport layer 4, the luminescent layer 5 and the cathode 6, sealing them in an airtight manner to block off oxygen and moisture. Placing the sealant 7 has effects of improving the reliability of the light emitting element 1 and of preventing the deterioration and degradation (or improving the durability) and the like.

Examples of a constituent material for the sealant 7 include Al, Au, Cr, Nb, Ta, Ti and a metal alloy containing them, silicon oxide, various resin materials and the like. Further, in the case where a conductive material is used as a constituent material for the sealant 7, it is preferable to place, if necessary, an insulating film between the sealant 7 and each of the anode 3, the hole transport layer 4, the luminescent layer 5 and the cathode 6 to prevent a short circuit therebetween.

Further, the sealant 7 can also be tabular and can be placed facing to the substrate 2, with some sealant, such as thermosetting resin, sealing therebetween.

An aspect of the invention is that an intermediate layer 8 mainly composed of a semiconductor material and/or an insulating material is interposed between the hole transport layer (carrier transport layer) 4 and the anode (one of the paired electrodes) 3.

As described above, it is preferable that the hole transport layer 4 and the luminescent layer 5 are mainly composed of a high-molecular material in the light of improving the properties of the light emitting element 1. In this case, however, there arise problems such as described below.

Specifically, as the transport efficiency of the hole (carrier) increases in the hole transport layer 4, the electron that is injected into the luminescent layer 5 from the cathode (the other electrode) 6, in other words, the electron that is a carrier having the opposite polarity from the hole, which is a carrier that is transported through the hole transport layer 4, also shows the tendency to easily move (pass through) toward the anode 3.

At this point, if there is an intermediate layer 8 placed between the hole transport layer 4 and the anode 3, the electron can be prevented from reaching (contacting) the anode 3. Specifically, the intermediate layer 8 acts as a block layer to inhibit the electron from contacting the anode 3.

Meanwhile, as the light emitting efficiency increases in the luminescent layer 5, the exciton generated as a result of the recombination of the electron and the hole in the layer shows the tendency to easily move through in the layer, then pass through the hole transport layer 4 and then reach (contact) the anode 3. This tendency is noticeable, particularly, in the case where the hole transport layer 4 and the luminescent layer 5 are formed simultaneously by phase separation.

At this point, if there is an intermediate layer 8 placed between the hole transport layer 4 and the anode 3, the exciton can be prevented from reaching and contacting the anode 3. Specifically, the intermediate layer 8 acts as a block layer to inhibit the exciton from contacting the anode 3.

In this way, placing an intermediate layer 8 can lower or dissolve, for example, the recombination rate of the electron and the hole on the anode 3 or the probability of quenching due to the contacting of the exciton to the anode 3. As a result, the light emitting efficiency and the durability (life span) can be improved in the light emitting element 1.

As a semiconductor material for constituting the intermediate layer 8, a compound with a bandgap as wide as possible (wide bandgap compound) is preferred. Although it is not particularly limited, examples of such a material include metal oxide such as vanadium oxide (V2O5), titanium oxide (Ti02), tin oxide (SnO2), tungstite (WO3) and niobium oxide (Nb2O3), and metal sulfide such as cadmium sulfide (CdS) and the like. These materials can be used singly or in combination of two or more.

Among these, metal oxide, in particular one that is mainly composed of vanadium oxide, is preferred as a semiconductor material. By using vanadium oxide as a main ingredient, the intermediate layer 8 can be made particularly excellent in the above-mentioned capability.

Further, because the vanadium oxide itself has a high transporting capacity of hole in particular in the case of the present embodiment, there is an advantage in that the degradation of the hole injection efficiency from the anode 3 into the hole transport layer 4 can be favorably prevented.

Meanwhile, examples of an insulating material for the intermediate layer 8 include silicon oxide (SiO2) and metal halogen compounds such as LiF, CsF and NaF. These materials can be used singly or in combination of two or more.

Among these, a material mainly composed of silicon oxide is preferred as an insulating material. By using silicon oxide as a main ingredient, the intermediate layer 8 can be made particularly excellent in the above-mentioned capability.

Although the average thickness of the intermediate layer 8 is not particularly limited, it is preferable to be smaller than 5 nm, more preferably to be between about 1 and 4 nm. Thus, the degradation of the hole injection efficiency from the anode 3 into the hole transport layer 4 can be prevented while it is ensured that the contacting of the electron and the exciton and the like to the anode 3 can be also prevented. In other words, by constituting the intermediate layer 8 using the above-mentioned materials as a main ingredient, the effect of preventing, in the above-mentioned range of film thickness of the intermediate layer 8, the electron and the exciton and the like from contacting the anode 3 can be fully exerted.

Further, although the above-mentioned effect can be fully exerted if the intermediate layer 8 is placed between the anode 3 and the hole transport layer 4, it is preferable that the intermediate layer 8 is in contact with at least either one of the anode 3 or the hole transport layer 4, more preferably with both. Thus, the enlargement of the light emitting element 1 (in particular, the thickening of the film) and the degradation of the injection efficiency of the hole (carrier) into the luminescent layer 5 can be prevented.

A light emitting element 1 such as described above can be manufactured, for example, in the following manner.

In the case of the following explanation, both the hole transport layer 4 and the luminescent layer 5 are mainly composed of a high-molecular material.

[1] First, the substrate 2 is prepared and then the anode 3 is formed on the substrate 2.

The anode 3 can be formed by using, for example, chemical vapor deposition (CVD) such as plasma CVD, thermal CVD or laser CVD, dry plating such as vacuum deposition, sputtering or ion plating, vapor deposition such as spraying, wet plating such as electrolytic plating, immersion plating or electroless plating, a sol-gel method, liquid phase deposition such as a MOD method, and bonding of a metallic foil, or the like.

[2] Next, the intermediate layer 8 is formed on the anode 3.

The intermediate layer 8 can be formed by using, for example, vapor deposition or liquid phase deposition or the like, such as mentioned above.

Among these, it is preferable that the intermediate layer 8 is formed using vapor deposition. According to vapor deposition, the intermediate layer 8 can be formed more finely, which makes the above-mentioned effects more noticeable.

[3] Next, an affinity improvement treatment is carried out onto the upper surface of the intermediate layer (base layer) 8 for improving its affinity (wetting properties) with a high-molecular material that constitutes the hole transport layer 4.

By doing this, it is further ensured that the high-molecular material constituting the hole transport layer 4 may be gathered to the side of the intermediate layer 8 (downside) in the fluid film when the hole transport layer 4 and the luminescent layer 5 are simultaneously formed, in the next process [4], by phase separation, which in turn ensures that the hole transport layer 4 and the luminescent layer 5 are formed separately from each other.

Examples of an affinity improvement treatment include a chemical modification treatment in which a chemical structure (building unit) including a part of the compounds that constitute the high-molecular material is deployed and a hydrophilic treatment in the case where the high-molecular material is hydrophilic. Of these two, the former is more preferred. In that case, the above-mentioned effects can be further improved.

Specifically, in the case, for example, where the high-molecular material has a triphenylamine structure, a chemical modification treatment in which an alkyl chain having such as amino group, triphenylamine (allylamine), phenyl group, benzyl group or the like on the edge is deployed on the surface of the intermediate layer 8 is carried out.

Here, as a treatment agent (sample agent) to be used in the chemical modification treatment, a compound (coupling agent) that has an atomic group to be deployed on one edge and has such as trimethylsilane, methylsilane, trichlorosilane or the like on the other edge can be used, for example, in the case where the intermediate layer 8 is mainly composed of metal oxide.

[4] Next, the hole transport layer 4 and the luminescent layer 5 are formed simultaneously by phase separation on the intermediate layer 8. This step can be carried out in the following manner.

First, a liquid material is prepared by dissolving the high-molecular material that constitutes the hole transport layer 4 and the high-molecular material that constitutes the luminescent layer 5 into a solvent (liquid medium).

Examples of a solvent include: inorganic solvents such as nitric acid, sulfuric acid, ammonia, hydrogen peroxide, water, carbon disulfide, carbon tetrachloride, and ethylene carbonate; and various organic solvents such as ketone-based solvents such as methyl ethyl ketone (MEK), acetone, diethyl ketone, methyl isobutyl ketone (MIBK), methyl isopropyl ketone (MIPK) and cyclohexanone, alcohol-based solvents such as methanol, ethanol, isopropanol, ethylene glycol, diethylene glycol (DEG) and glycerol, ether-based solvents such as diethyl ether, diisopropyl ether, 1,2-dimethoxy ethane (DME), 1,4-dioxane, tetrahydrofuran (THF), tetrahydropyran (THP), anisole, diethylene glycol dimethyl ether (diglyme) and diethylene glycol ethyl ether (Carbitol), cellosolve-based solvents such as methyl cellosolve, ethyl cellosolve and phenyl cellosolve, aliphatic hydrocarbon-based solvents such as hexane, pentane, heptane and cyclohexane, aromatic hydrocarbon-based solvents such as toluene, xylene and benzene, aromatic heterocyclic compound-based solvents such as pyridine, pyrazine, furan, pyrrole, thiophene and methylpyrrolidone, amide-based solvents such as N,N-dimethylformamide (DMF) and N,N-dimethylacetamide (DMA), halogen compound-based solvents such as chlorobenzene, dichloromethane, chloroform and 1,2-dichloroethane, ester-based solvents such as ethyl acetate, methyl acetate and ethyl formate, sulfur compound-based solvents such as dimethyl sulfoxide (DMSO) and sulfolane, nitrile-based solvents such as acetonitrile, propionitrile and acrylonitrile, organic acid-based solvents such as formic acid, acetic acid, trichloroacetic acid and trifluoroacetic acid, and mixed solvents containing them.

Among these, a nonpolar solvent is preferred as a solvent. Such examples include aromatic hydrocarbon-based solvents such as xylene, toluene, cyclohexylbenzene, dihydrobenzofuran, trimethylbenzene and tetramethylbenzene, aromatic heterocyclic compound-based solvents such as pyridine, pyrazine, furan, pyrrole, thiophene and methylpyrrolidone, and aliphatic hydrocarbon-based solvents such as hexane, pentane, heptane and cyclohexane. These materials can be used singly or in combination of two or more.

Next, the liquid material is applied on the intermediate layer 8 to form a fluid film.

Various kinds of application methods such as a spin coating method, a casting method, a micro gravure coating method, a gravure coating method, a bar coating method, a roll coating method, a wire-bar coating method, a dip coating method, a spray coating method, a screen printing method, a flexographic printing method, an offset printing method, an ink-jet printing method and the like can be employed, as an application method for the liquid material. According to such an application method, a fluid film can be formed relatively easily.

Next, the solvent is removed from the fluid film. In the fluid film, after the solvent has been removed, the high-molecular material constituting the hole transport layer 4 is resolved and hardened on the side of the intermediate layer 8 (the anode 3) while the high-molecular material constituting the luminescent layer 5 is resolved and hardened on the side of the cathode 6, forming the hole transport layer 4 and the luminescent layer 5. Specifically, the hole transport layer 4 and the luminescent layer 5 are formed simultaneously by phase separation.

At this point, the condition of the phase separation of the high-molecular material constituting the hole transport layer 4 and the high-molecular material constituting the luminescent layer 5 can be controlled by appropriately setting at least one condition among the conditions, such as the type of solvent, the weight-average molecular weight of the high-molecular material constituting the hole transport layer 4 and its content in the liquid material, the weight-average molecular weight of the high-molecular material constituting the luminescent layer 5 and its content in the liquid material, the removing speed of the solvent, the atmosphere of when the solvent is removed, the surface condition of the lower layer (intermediate layer 8) on which the liquid material is applied.

For example, it is preferable to select, as a high-molecular material constituting the hole transport layer 4, a material the weight-average molecular weight of which is smaller than the weight-average molecular weight of the high-molecular material constituting the luminescent layer 5.

[5] Next, the cathode 6 is formed on the luminescent layer 5.

The cathode 6 can be formed using, for example, vacuum deposition, sputtering process, bonding of a metallic foil, or the like.

[6] Next, the sealant 7 is laid over in a manner of covering the anode 3, the hole transport layer 4, the luminescent layer 5 and the cathode 6, connecting to the substrate 2.

The light emitting element 1 according to the embodiment of the invention is manufactured through the above-mentioned processes.

In such a light emitting element 1, it is acceptable to place another layer having a similar configuration with the intermediate layer 8 between the luminescent layer 5 and the cathode 6.

Although the carrier transport layer is applied to the hole transport layer in the embodiment, the carrier transport layer can be also applied to the electron transport layer in an embodiment of the invention.

In such a case, examples of a high-molecular material constituting the electron transport layer, in the case of constituting the electron transport layer using a high-molecular material as a main ingredient, include, for example, oxaziazole high-molecular and triazole high-molecular and the like.

Such a light emitting element 1 can be used, for example, as a light source and the like. Further, a display device (a display unit according to an aspect of the invention) can be configured by placing a plurality of light emitting elements 1 in a matrix.

The drive system for the display device is not particularly limited. Either active matrix system or passive matrix system is applicable.

Next, an example of a display device having a display unit according to an aspect of the invention will be described.

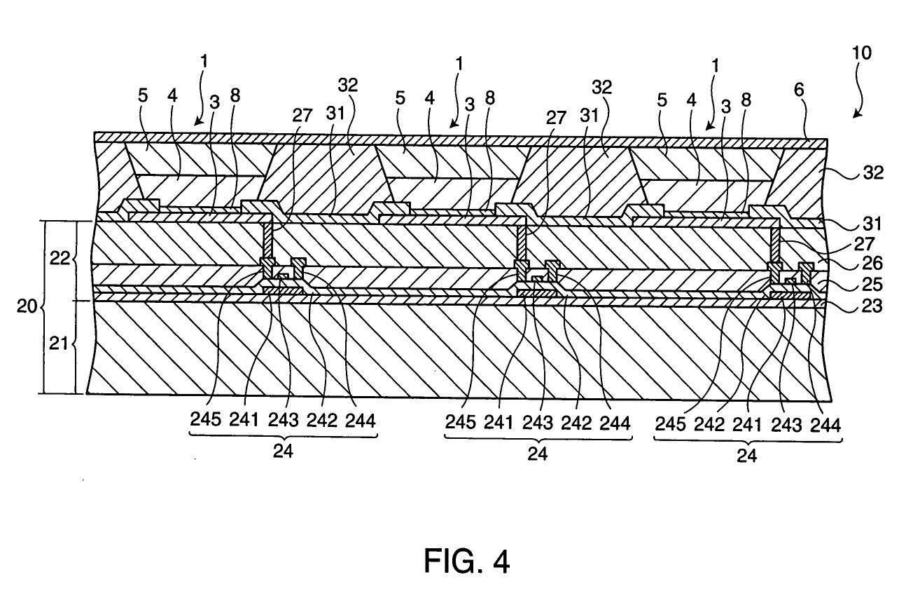

FIG. 4 is a drawing showing the longitudinal section of a display device having a display unit according to an embodiment of the invention.

The display device 10 shown in FIG. 4 is composed of a base substance 20 and a plurality of light emitting elements 1 that are placed on the base substance 20.

The base substance 20 includes a substrate 21 and a circuit unit 22 that is formed on the substrate 21.

The circuit unit 22 includes a protective layer 23 that is composed, for example, of a silicon oxide layer and is formed on the substrate 21, a driving TFT (switching element) 24 that is formed on the protective layer 23, a first interlayer insulating layer 25 and a second interlayer insulating layer 26.

The driving TFT 24 includes a semiconductor layer 241 that is composed of silicon, a gate insulating layer 242 that is formed on the semiconductor layer 241, a gate electrode 243 that is formed on the gate insulating layer 242, a source electrode 244 and a drain electrode 245.

On such a circuit unit 22, a light emitting element 1 is respectively placed directly opposite to each driving TFT 24. Adjacent light emitting elements 1 are respectively comparted by a first division unit 31 and a second division unit 32.

In the embodiment, the anode 3 of each light emitting element 1 constitutes a pixel electrode and is electrically connected to the drain electrode 245 of each driving TFT 24 via a wiring 27. Further, the cathode 6 of each light emitting element 1 acts as a common electrode.

Then, a sealant (not shown) is connected to the base substance 20 in a manner of covering each light emitting element 1 so as to seal them.

The display device 10 can be either in monochrome or in color. In the latter case, a light emitting material may be selected for each light emitting element 1.

Such a display device 10 (display unit according to an aspect of the invention) can be built into various types of electronic apparatuses.

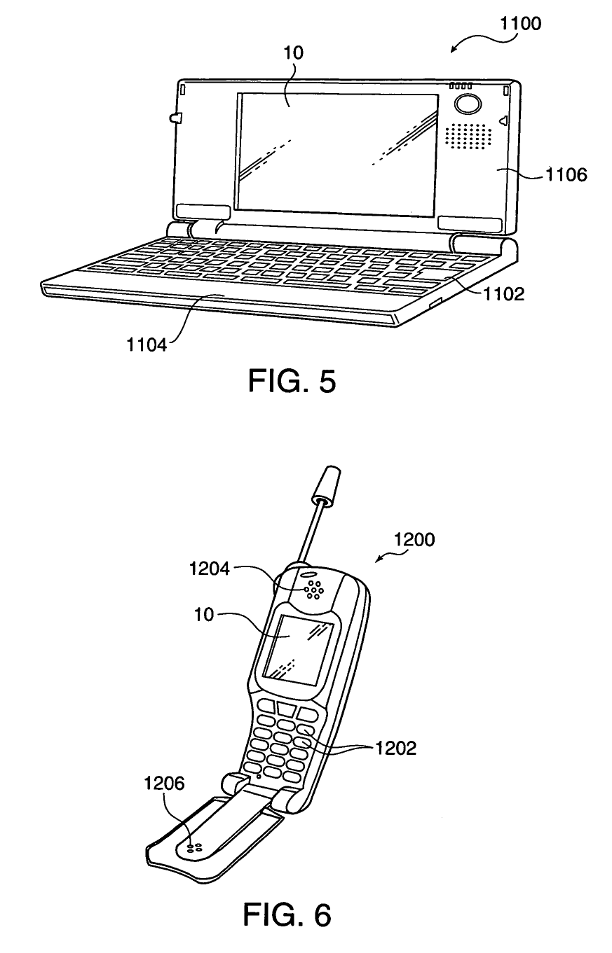

FIG. 5 is an oblique diagram showing the configuration of a mobile (or notebook) personal computer having an electronic apparatus according to an aspect of the invention.

In the drawing, the personal computer 1100 is composed of a main unit 1104 having a keyboard 1102, and a display unit 1106 having a display section, wherein the display unit 1106 is rotatably supported to the main unit 1104 via a hinge structure.

In the personal computer 1100, the display section of the display unit 1106 is composed of the above-mentioned display device 10.

FIG. 6 is an oblique diagram showing the configuration of a mobile phone (including a PHS) having an electronic apparatus according to an aspect of the invention.

In the drawing, the mobile phone 1200 includes a plurality of control buttons 1202, an earhone 1204, a mouthpiece 1206 and a display section.

In the mobile phone 1200, the display section is composed of the above-mentioned display device 10.

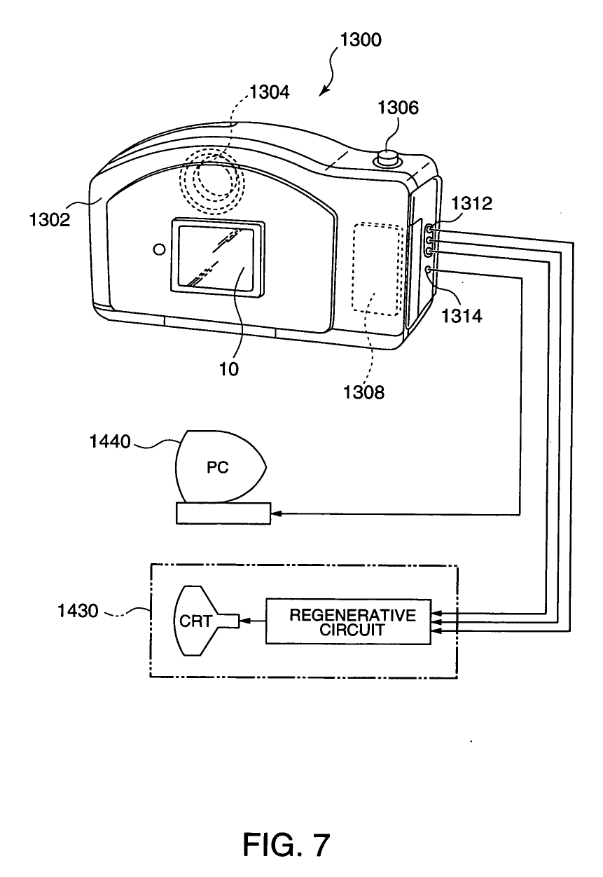

FIG. 7 is an oblique diagram showing the configuration of a digital still camera having an electronic apparatus according to an aspect of the invention. In the drawing, the interfacing with external devices is also shown in a simple way.

Here, in a usual camera, a metallic silver film is exposed by the optical image of the object. Meanwhile, in a digital still camera 1300, the optical image of the object is photoelectrically transferred by an imaging element such as a CCD (Charge Coupled Device) to generate an imaging signal (picture signal).

A display section is placed on the backside of a case (body) 1302 of the digital still camera 1300, with a configuration to display images according to the imaging signals received from the CCD, acting as a finder to display an object as an electronic image.

In the digital still camera 1300, the display section is composed of the display device 10.

A circuit board 1308 is placed in the inside of the case. On the circuit board 1308, a memory for storing (memorizing) an imaging signal is placed.

Further, on the front surface side of the case 1302 (on the rear surface side in the drawing), a photo acceptance unit 1304 including an optical lens (imaging optics), CCD or the like is placed.

When a photographer checks the object image displayed on the display section and pushes a shutter button 1306, the imaging signal at that point is transferred from the CCD to the memory of the circuit board 1308 and is stored therein.

Further, in the digital still camera 1300, a video signal output terminal 1312 and a data communication input/output terminal 1314 are placed on the side surface of the case 1302. Further, a television monitor 1430 is connected to the video signal output terminal 1312 and a personal computer 1440 is connected to the data communication input/output terminal 1314, respectively, as shown in the drawing, if necessary. Moreover, the imaging signal stored in the memory of the circuit board 1308 is outputted to the television monitor 1430 or to the personal computer 1440 according to predetermined operations.

In addition to for the personal computer (mobile personal computer) in FIG. 5, for the mobile phone in FIG. 6 and for the digital still camera in FIG. 7, electronic apparatuses according to an aspect of the invention can be applied for such as televisions, video cameras, video tape recorders (viewfinder types or monitor types), laptop personal computers, car navigation systems, pagers, electronic organizers (including those with communication capability), electronic dictionaries, calculators, electronic game consoles, word processors, workstations, videophone systems, security television monitors, electronic binoculars, point of sale terminals, apparatuses having a touch panel (such as a cash dispenser for financial institutions, automatic ticket machines), medical equipments (such as an electronic thermometer, a blood pressure manometer, a blood sugar meter, an electrocardiographic display system, an ultrasonic diagnostic equipment, an endoscopic display unit), fishfinders, various measuring equipments, various measuring gauges (such as measuring gauges for vehicles, aircraft and marine vessels and the like), flight simulators, various monitors, projection display systems such as a projector, and the like.

Although, in the above description, a light emitting element, a display unit and an electronic apparatus are described according to the embodiments shown in the drawings, the invention is not limited to these.

### EMBODIMENTS

Practical embodiments of the invention will be now described.

1. Manufacturing of a light emitting element

### Embodiment Example 1

[1] First, a transparent glass substrate with an average thickness of 0.5 mm is prepared.

[2] Next, an ITO electrode (anode) with an average thickness of 100 nm is formed on the substrate with a sputtering system.

[3] Next, a vanadium oxide (V205) layer (intermediate layer) with an average thickness of 3 nm is formed on the ITO electrode with vacuum deposition.

[4] Next, an ethanol solution of NH2(CH2)5SiCI3 (silane coupling agent) with a 0.1 wt percent concentration is applied on the vanadium oxide layer with a spin coating method (2000 rpm) and then is dried.

[5] Next, a liquid material is prepared by adjoining polyphenylamin polymer molecule (weight-average molecular weight: 5000) shown in the above-described chemical diagram 1 and poly(dioctylfluorene-alt-benzothiadiazole) (F8BT) (weight-average molecular weight: 10000) to xylene, as a constituent material for the hole transport layer and as a constituent material for the luminescent layer, respectively.

Here, the content of the polyphenylamin polymer molecule is set to be 0.5 wt percent and the content of the polyfluorene polymer molecule is set to be 1.5 wt percent.

Then, the liquid material applied on the vanadium oxide layer with a spin coating method (2000 rpm) and then is dried.

Here, the drying condition of the liquid material is to be atmospheric at room temperature.

Thus, the hole transport layer and the luminescent layer are formed by phase separation.

The average thickness of the hole transport layer is set to be 30 nm and the average thickness of the luminescent layer is set to be 50 nm.

[6] Next, an AlLi electrode (cathode) with an average thickness of 300 nm is formed on the luminescent layer by vacuum deposition.

Next, a polycarbonate protective cover (sealant) is laid over in a manner of covering each of the formed layers, and is fixated and sealed with an ultraviolet setting resin to accomplish a light emitting element.

### Embodiment Example 2

A light emitting element is manufactured in the same way with the embodiment example 1, except that a titanium oxide (TiO2) layer (intermediate layer) with an average thickness of 3 nm is formed on the ITO electrode with vacuum deposition in the process [3].

### Comparative Example

A light emitting element is manufactured in the same way with the embodiment example 1, except that the process [3] is omitted.

2. Evaluation

The light emitting efficiency and the life span are respectively evaluated as for the light emitting elements manufactured according to each of the embodiment examples and to the comparative example.

The evaluation of the light emitting efficiency is carried out by measuring the electric current value and the brightness, using a luminance meter, while applying voltage from 0 to 6V with a power system.

The evaluation of the life span is carried out by a constant current driving with initial brightness of 400 cd/m².

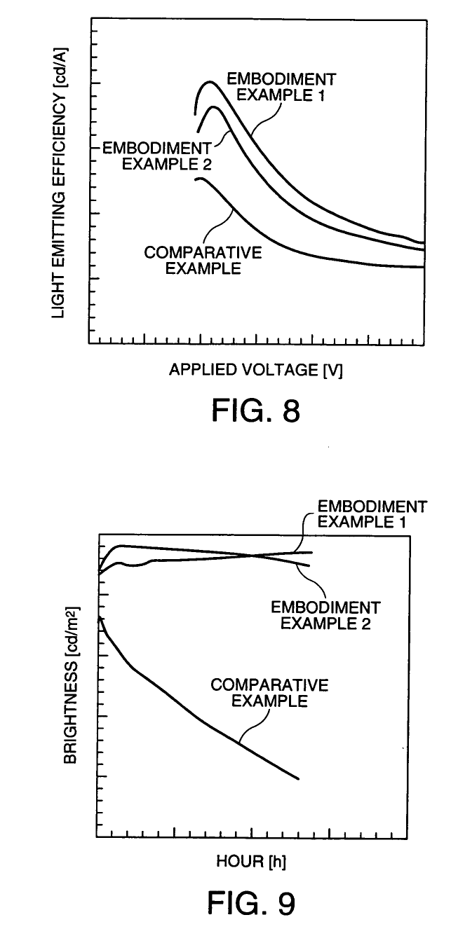

The results are shown in FIG. 8 and FIG. 9, respectively.

The light emitting efficiency of the light emitting elements in the both embodiments is definitely superior to the light emitting efficiency of the light emitting elements in the comparative example, as shown in FIG. 8.

Further, as shown in FIG. 9, it is confirmed that the life span of the light emitting elements in the both embodiments is definitely longer than the life span of the light emitting elements in the comparative example.

In particular, a light emitting element that has a vanadium oxide layer as an intermediate layer has a superior light emitting efficiency and a longer life span.

Although a sufficient light emitting efficiency and a life span (durability) are confirmed also as for the light emitting elements manufactured in the same way with the embodiment example 1 except that the average thickness of the vanadium oxide layer is 5 nm, the tendency shows that the properties are more improved in the light emitting elements in the embodiment example 1.

Further, the same results as mentioned above can be obtained when light emitting elements are manufactured in the same way with the embodiment example 1 by using SiO2 (an insulating material) and combining an insulating material and a semiconductor material for the intermediate layer.

What is claimed is:

1. A light emitting element, comprising:
a first electrode;
a second electrode;
a luminescent layer that is placed between the first electrode and the second electrode;
a carrier transport layer that is placed between the first electrode and the second electrode; and
an intermediate layer that is placed between the carrier transport layer and the first electrode, wherein at least one of either the luminescent layer or the carrier transport layer contains a high-molecular material and the intermediate layer contains at least either of a semiconductor material or an insulating material.

2. The light emitting element according to claim 1, wherein the carrier transport layer is placed between the luminescent layer and the first electrode.

3. The light emitting element according to claim 1, wherein the semiconductor material is mainly composed of vanadium oxide.

4. The light emitting element according to claim 1, wherein the insulating material is mainly composed of silicon oxide.

5. The light emitting element according to claim 1, wherein the intermediate layer has an average thickness of less than 5 nm.

6. The light emitting element according to claim 1, wherein the intermediate layer is formed by vapor deposition.

7. The light emitting element according to claim 1, wherein the intermediate layer is in contact with the first electrode.

8. The light emitting element according to claim 1, wherein the intermediate layer is in contact with the carrier transport layer.

9. The light emitting element according to claim 1, wherein the luminescent layer contains a high-molecular material and the intermediate layer has a function of preventing the exciton generated in the luminescent layer from contacting the first electrode.

10. The light emitting element according to claim 9, wherein the high-molecular material constituting the luminescent layer is polyfluorene or any of its derivatives.

11. The light emitting element according to claim 1, wherein the carrier transport layer contains a high-molecular material and the intermediate layer has a function of preventing the carrier injected from the second electrode from reaching the first electrode.

12. The light emitting element according to claim 11, wherein the carrier transport layer is a hole transport layer and the high-molecular material constituting the hole transport layer is poly-arylamin or any of its derivatives.

13. The light emitting element according to claim 1, wherein the luminescent layer and the carrier transport layer are formed simultaneously by phase separation.

14. A display unit comprising a light emitting element according to claim 13.

15. An electronic apparatus comprising a display unit according to claim 14.
